(19) United States
(12) Patent Application Publication
(10) Pub. No.: US 2012/0099256 A1
(43) Pub. Date: Apr. 26, 2012

(54) SENSOR INCLUDING RETRACTABLE POWER ADAPTER CORD

(75) Inventors: Christopher J. Fawcett, Charlotte, NC (US); Kai-Sheng Cheng, Charlotte, NC (US)

(73) Assignee: InVue Security Products Inc., Charlotte, NC (US)

(21) Appl. No.: 13/271,277

(22) Filed: Oct. 12, 2011

Related U.S. Application Data
(60) Provisional application No. 61/405,261, filed on Oct. 21, 2010.

(51) Int. Cl. H05K 7/00

(52) U.S. Cl. 361/679.01

(57) ABSTRACT

A sensor for attachment to an item of merchandise includes a housing defining an interior cavity and an electrical circuit disposed within the interior cavity. A power adapter cord having a length and containing one or more conductors is connected at one end to the electrical circuit and at the other end to the item of merchandise to supply electrical power to the item of merchandise. At least a portion of the length of the power adapter cord is retractable into the interior cavity of the housing by a wheel disposed and rotatably mounted within the interior cavity. The wheel has a large diameter portion and a small diameter hub portion that depends from the large diameter portion and on which the retractable portion of the length of the power adapter cord is wound when the wheel is rotated relative to the housing.

### CROSS REFERENCE TO RELATED APPLICATION

This non-provisional application claims the benefit of U.S. Provisional Application No. 61/405,261 filed on Oct. 21, 2010, the entire disclosure of which is incorporated herein by reference.

### FIELD OF THE INVENTION

The present invention relates generally to merchandise security devices for protecting items of merchandise. More particularly, the invention is a sensor including a retractable power adapter cord configured for attachment to an item of merchandise for use with a merchandise security device to protect the item of merchandise from theft.

### BACKGROUND OF THE INVENTION

It is common practice for retailers to display relatively expensive items of merchandise on a merchandise security device, such as a display stand, alarm module, secure fixture, or the like. The security device typically displays an item of merchandise so that a potential purchaser may readily view and, in some instances, operate the item before deciding to make a purchase. At the same time, the item of merchandise is typically secured on the security device so as to prevent, or at least deter, theft of the item. The merchandise security device may also include an audible and/or visible alarm that is activated to alert store personnel in the event that a potential thief attempts to remove the item from the security device.

Oftentimes, the item of merchandise must be provided with electrical power to permit the potential purchaser to test the operation of the item. While most such items of merchandise include an internal source of power (e.g. battery), it is not always desirable or practical to utilize the item's own power source since a battery requires periodic replacement or recharging. In addition, the battery charge may dissipate during display and render the item of merchandise inoperable, and thereby, possibly discourage the potential purchaser from purchasing the item.

It is known for a merchandise security device to include an adapter cord, also referred to herein as a “power adapter cord,” for supplying power to an item of merchandise from an external source of power (e.g. DC transformer). However, use of a power adapter cord (commonly referred to as a “pigtail”) requires routing and managing the cord from the merchandise security device to the item of merchandise during use. When not in use, the power adapter cord must be stored in a manner that does not interfere with the display of an item of merchandise, or with the examination and/or operation of the item by a potential purchaser. In most instances, a standardized power adapter cord has a length that is longer than necessary for the item of merchandise being displayed. As a result, the power adapter cord can become twisted, tangled or bent excessively. In such instances, the display of the item of merchandise may be aesthetically unpleasant. Worse yet, the item of merchandise may not operate properly due to a short or kink in the wiring of the power adapter cord.

Accordingly, there exists an unresolved need for a sensor including a power adapter cord for use with a merchandise security device to supply electrical power to an item of merchandise displayed on the security device that overcomes the disadvantages of the known power adapter cords. There exists a further, and more particular, need for a sensor including a power adapter cord configured for attachment to an item of merchandise for use with a merchandise security device that does not interfere with the display of the item, or with the examination and/or operation of the item by a potential purchaser. There exists a specific need for a sensor including a power adapter cord for supplying electrical power to an item of merchandise displayed on a merchandise security device that does not become twisted, tangled or bent excessively during use or storage.

### BRIEF DESCRIPTION OF THE DRAWINGS

The detailed description of the invention provided herein may be better understood with reference to the accompanying drawing figures, which depict one or more exemplary embodiments of a sensor including a retractable power adapter cord in accordance with the invention for supplying electrical power to an item of merchandise displayed on a merchandise security device.

FIG. 1 is a side elevation view of a sensor including a retractable power adapter cord according to the invention shown with the power adapter cord in a retracted position.

FIG. 2 is a top plan view of the sensor of FIG. 1.

FIG. 3 is an exploded perspective view of the sensor of FIG. 1.

FIG. 4 is a perspective view showing a retractable power adapter cord according to the invention in greater detail.

FIG. 5 is another perspective view of the retractable power adapter cord of FIG. 4.

### DETAILED DESCRIPTION OF EXEMPLARY EMBODIMENTS OF THE INVENTION

Referring now to the accompanying drawing figures wherein like reference numerals denote like elements throughout the various views, one or more exemplary embodiments of a sensor including a retractable power adapter cord according to the invention are shown. Sensors according to the invention are configured for attachment to an item of merchandise and for use with a merchandise security device to protect the item of merchandise from theft. Merchandise security devices suitable for use with the invention include, but are not limited to, a display stand, an alarm module, a secure fixture, and the like. However, a retractable power adapter cord according to the invention is useable with any merchandise security device or merchandise display system that requires power to be supplied to an item of merchandise from an external power source, such as a direct current (DC) transformer in electrical communication with a source of alternating current (AC) electricity.

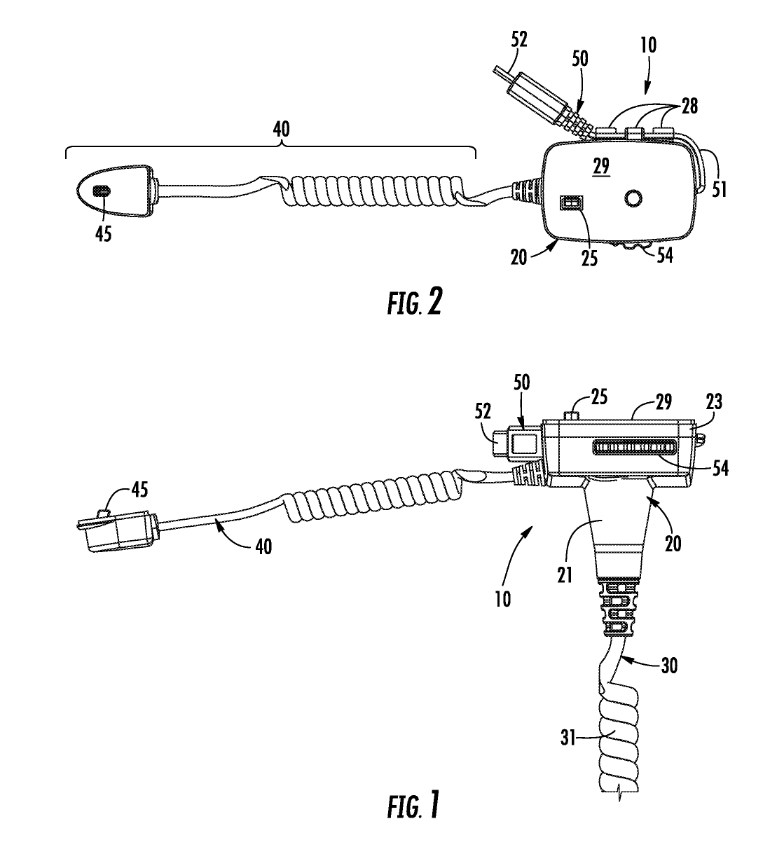

An exemplary embodiment of a sensor, indicated generally at 10, for use with a merchandise security device (not shown) to supply electrical power to an item of merchandise to be displayed, for example in a retail store, is shown in FIGS. 1-3. The sensor 10 includes a housing 20 comprising a bottom portion 21 and a top portion 23. The bottom portion 21 defines an internal cavity 22 (FIG. 3) sized, shaped and configured to contain the structural and electrical components of the sensor. The sensor 10 further includes a main power cable 30 comprising a plurality of electrical or optical conductors 32 (FIG. 3). As shown, the power cable 30 is flexible and elastic and has one or more helical coils 31 that allow the power cable to be extended (i.e. stretched) and returned to its original length when released. Extension of the coils 31 of power cable 30 permits a potential purchaser to more closely examine and, in some instances, operate an item of merchandise attached to the sensor 10. In the embodiment shown herein, conductors 32 are connected at one end to a jack or plug 34 configured in a conventional manner to be in communication with an external source of power (not shown). At the opposite end, conductors 32 are connected to an electrical circuit, such as a printed circuit board (PCB) 24 disposed within the internal cavity 22 defined by the bottom portion 21 of housing 20. As used herein the term “electrical circuit” is intended to broadly include any electrical connection and/or coupling for communicating electrical power from an external source of power, or alternatively from an internal source of power, to the retractable power adapter cord, as will be described hereafter. As shown, conductors 32 may be routed from the power cable 30 through a strain relief 35 and a conductor ferrule 36 to PCB 24.

PCB 24 is in electrical or optical communication with a first, or primary, sensor switch 25 that extends through the top portion 23 of housing 22. Switch 25 is configured to be depressed against a compression spring 26 or the like when the item of merchandise is attached to the sensor 10, as will be described. When the item of merchandise is subsequently removed from sensor 10, switch 25 extends outwardly from housing 20 (as best shown in FIG. 1) under the influence of compression spring 26. The state of switch 25 is monitored in a known manner by electronics on PCB 24 that activate an audible and/or visible alarm when switch 25 extends outwardly under the influence of spring 26 after having been depressed when the item of merchandise is attached to the upper surface of top portion 23 of sensor 10. The extension of switch 25 may create an electrical “open” circuit condition or an electrical “closed” circuit condition, as desired, to indicate an “unsecured” or “alarm” state. PCB 24 may also be in electrical or optical communication with a second, or auxiliary, sensor switch 45 through a sensor cable, or lanyard 40. Switch 45 operates in substantially the same manner as switch 25 and is available to be attached to a removable portion of the item of merchandise, such as a lens of a camera or a battery pack of a mobile telephone.

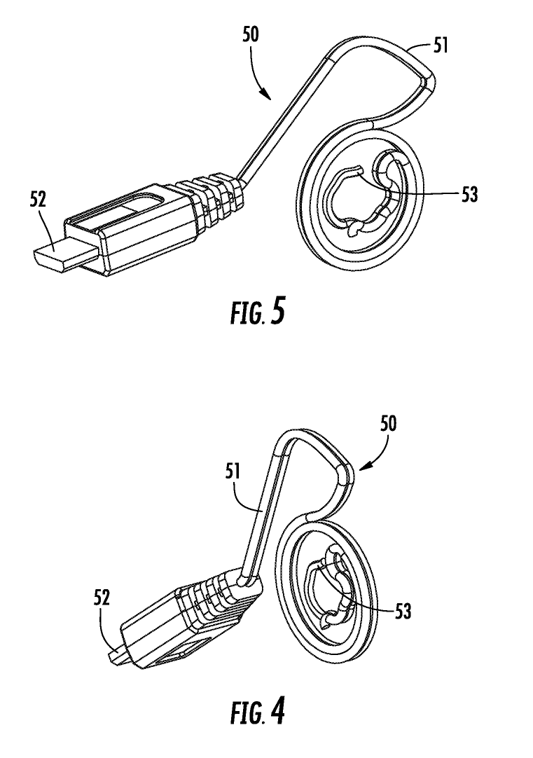

PCB 24 is also in electrical communication with a power adapter cord 50 configured in accordance with the invention and shown in greater detail in FIGS. 4 and 5. Power adapter cord 50 comprises conductors (not shown) for supplying electrical power to an item of merchandise attached to the sensor 10. The item of merchandise may be any type of electronics and the power adapter cord 50 may be any cable, cord, lanyard or conduit configured for use with the particular type of electronics. For example, the item of merchandise may be a mobile (e.g. cellular) telephone having a micro USB port for receiving a power cord (not shown) operable to power the mobile telephone and/or to charge a rechargeable battery used with the mobile telephone. As a result, the power adapter cord 50 will be configured with a micro USB plug 52 (as shown herein) at its free end for connection to the micro USB jack or port of the mobile telephone. In this manner, the power adapter cord 50 may power the mobile telephone for display and/or operation and/or, alternatively, may be used to recharge a rechargeable battery of the mobile telephone.

A retailer may prefer that the power adapter cord 50 remain electrically connected to the mobile telephone to supply power at all times while the mobile telephone is on display during the hours of operation of the store. Alternatively, the retailer may prefer that the power adapter cord 50 be used to recharge the rechargeable battery of the mobile telephone while the store is closed or when the mobile telephone is not on display. In the former instance, it is desirable that the power adapter cord 50 is as inconspicuous as possible (i.e. concealed) so that the display is aesthetically pleasing and to discourage a potential thief or vandal from attempting to disconnect the power adapter cord from the mobile telephone. In the latter instance, it is desirable that the power adapter cord 50 is removable so that the display remains aesthetically pleasing, and further, so that a potential thief or vandal is not encouraged to attempt to disconnect the power adapter cord from the mobile telephone.

A removable power adapter cord 50 is subject to becoming misplaced, lost or damaged. Accordingly, the present invention provides a sensor 10 including a power adapter cord 50 that remains permanently attached to the sensor and is at least partially retractable into the housing 20 of the sensor. To that end, sensor 10 further comprises a wheel 54 disposed and rotatably mounted within the interior cavity 22 defined by the bottom portion 21 of the housing 20. Wheel 54 has a large diameter portion that is wider than the bottom portion 21 of the housing 20, and as a result, extends laterally outward of the housing through an opening or slot 27 (FIG. 3) formed in the bottom portion of the housing. Wheel 54 further has a small diameter hub portion 56 that depends from the larger diameter portion upwardly (as shown herein) within the interior cavity 22 defined by the bottom portion 21 of the housing. The end 53 of the power adapter cord 50 electrically connected to PCB 24 is wound around the hub portion 56 of the wheel 54. As wheel 54 is rotated relative to the housing 20 in a first direction (e.g. clockwise), the sheath 51 containing the electrical conductors of the power adapter cord 50 is wound around the hub portion 56. Consequently, the length of the sheath 51 outside the housing 22 is retracted into the interior cavity 22 defined by the bottom portion 21 of the housing.

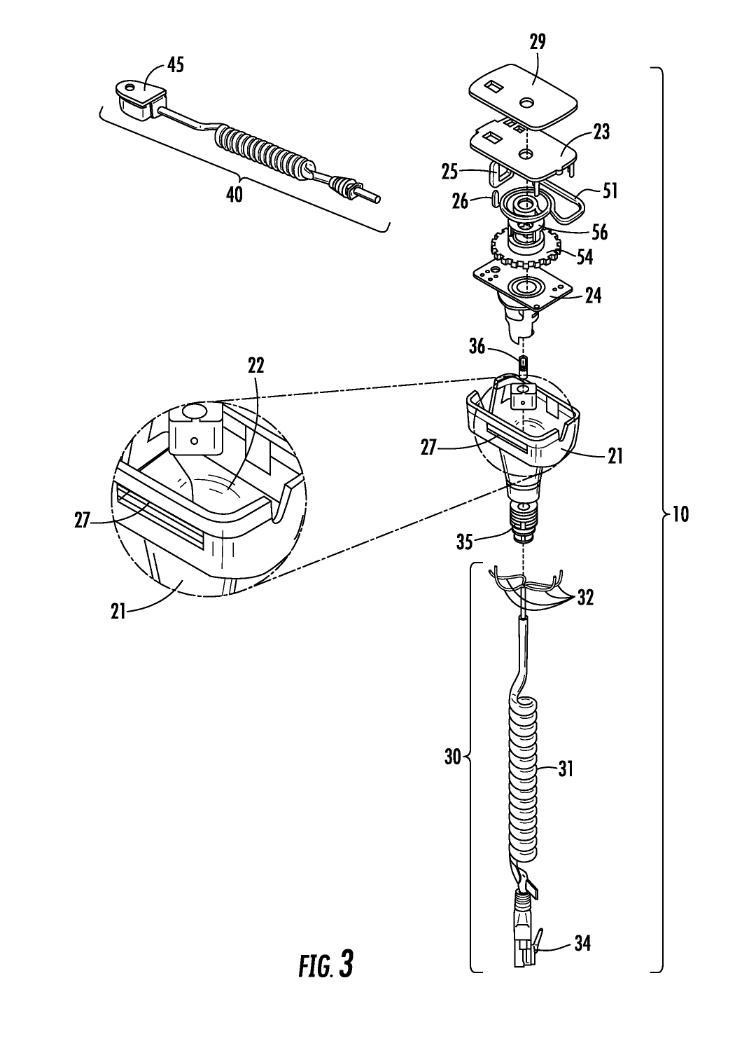

Wheel 54 may be rotatably mounted within the housing 20 relative to PCB 24 in any suitable manner as long as rotation of the wheel, and in particular, the hub portion 56 of the wheel does not interfere with the electrical connection between the end 53 of the power adapter cord 50 and the PCB. For this reason, it may be desirable to provide strain relief between the power adapter cord 50 and the hub portion 56 of the wheel 54. When the desired length of the sheath 51 of the power adapter cord 50 has been retracted into the housing 20 (as shown in FIGS. 1 and 2), the length of the sheath of the power adapter cord remaining outside the housing (except for the plug 52 at the free end of the power adapter cord) may be restrained by one or more clips 28 (FIG. 2) formed on the outer periphery of the bottom portion 21 of the housing opposite the slot 27. Clips 28 ensure that the sensor 10 of the merchandise security device remains aesthetically pleasing when an item of merchandise is attached to the sensor, but the power adapter cord 50 is not connected to the item of merchandise. When the power adapter cord 50 is connected to the item of merchandise, a suitable length of the sheath 51 of the power adapter cord may be restrained by the clips 28 so that the display of the item of merchandise on the merchandise security device remains aesthetically pleasing.

In use, the power cable 30 of the sensor 10 is routed to an external source of power and conductors 32 are electrically connected to the external source of power through jack 34. Preferably, sensor 10 is supported on a merchandise security device (not shown), such as an alarm module, display stand or the like, for protecting an item of merchandise on display in a retail store from theft. Next, the item of merchandise to be displayed on the merchandise security device is attached to the sensor 10. The item of merchandise may be attached to the sensor 10, for example, by a lasso, lanyard, cable tie or similar means that makes it difficult for a potential thief to detach the item of merchandise from the sensor. Preferably, however, sensor 10 further includes a relatively thin layer of a pressure sensitive adhesive (PSA) 29, such as double-sided tape, with one side of the PSA adhered to the top portion 23 of the housing 20 and the other side of the PSA adhered to a relatively flat surface of the item of merchandise. Regardless, the item of merchandise is attached to the top portion 23 of the housing 20 such that the sensor switch 25 is depressed to thereby arm the alarm of the sensor 10 in a known manner. The second, or auxiliary sensor switch 45, may then be attached to a removable portion of the item of merchandise in a similar manner. If the item of merchandise is to be powered by the external source of power, a desired length of the sheath 51 of the power adapter cord 50 is removed from the housing 20 by pulling on plug 52 to rotate the hub portion 56 of wheel 54, and thereby dispense the sheath from the internal cavity 22 of the housing. Plug 52 is then inserted into the micro USB jack or port provided on the item of merchandise and wheel 54 is rotated to retract any excess length of the sheath 51 of the power adapter cord 50 into the housing 20. If desired, a portion of the length of the sheath 51 that remains outside the housing 20 may be inserted into the clips 28 formed on the outer periphery of the bottom portion 21 of the housing to restrain the sheath, and thereby provide strain relief for the power adapter cord 50.

The foregoing detailed description and accompanying drawing figures has illustrated one or more exemplary embodiments of a sensor including a retractable power adapter cord for supplying electrical power to an item of merchandise. As shown and described herein, the sensor is configured for attachment to the item of merchandise and for use with a merchandise security device to display the item of merchandise, for example in a retail store, in an operable condition. Preferred embodiments of a sensor including a retractable power adapter cord and methods of using the same have been shown and described herein for purposes of illustrating and enabling the best mode of the invention. Those of ordinary skill in the art, however, will readily understand and appreciate that numerous variations and modifications of the invention may be made without departing from its intended spirit and scope. Accordingly, all such variations and modifications are intended to be encompassed by the appended claims. In particular, it will be readily understood and appreciated by those skilled in the art that a retractable power adapter cord according to the invention may be used with any apparatus, device, system or the like for supplying electrical power to any item of merchandise, product, article or the like that is configured to receive electrical power, or to be recharged with electrical power, from an external source of power.

That which is claimed is:

1. A sensor configured for attachment to an item of merchandise comprising:
a housing defining an interior cavity;
an electrical circuit at least partially disposed within the interior cavity of the housing; and
a power adapter cord having a length and containing one or more conductors connected to the electrical circuit at one end and adapted to be connected to the item of merchandise at the other end;
wherein at least a portion of the length of the power adapter cord is retractable into the interior cavity defined by the housing.

2. A sensor according to claim 1, wherein the power adapter cord comprises a sheath for containing the one or more conductors therein and further comprises a connector having a plug at the other end configured to be received within a jack provided on the item of merchandise.

3. A sensor according to claim 1, further comprising a small diameter hub portion disposed and rotatably mounted within the interior cavity defined by the housing and wherein the hub portion is rotatable relative to the housing to retract the retractable portion of the length of the power adapter cord into the interior cavity.

4. A sensor according to claim 1, wherein the retractable portion of the length of the power adapter cord is adapted to be wound onto a hub portion disposed and rotatably mounted within the interior cavity defined by the housing.

5. A sensor according to claim 1, further comprising a wheel disposed and rotatably mounted within the interior cavity defined by the housing, the wheel having a large diameter portion that extends laterally outward of the housing and a small diameter hub portion that depends from the wheel for receiving the retractable portion of the length of the power adapter cord.

6. A sensor according to claim 5, wherein the wheel is rotatable relative to the housing to retract the retractable portion of the length of the power adapter cord into the interior cavity defined by the housing.

7. A sensor according to claim 1, further comprising a main power cable containing one or more conductors connected to the electrical circuit at one end and adapted to be connected to an external source of power at the other end.

8. A sensor according to claim 7, wherein the main power cable is flexible and elastic so that the main power cable is adapted to be extended and returned to its original length.

9. A sensor according to claim 8, wherein the main power cable comprises one or more helical coils.

10. A sensor according to claim 1, further comprising a primary switch configured for indicating that the item of merchandise attached to the sensor has been subsequently detached from the sensor.

11. A sensor according to claim 10, wherein the primary switch is connected to the electrical circuit and is biased by a spring outwardly from the housing when the item of merchandise is not attached to the sensor and wherein the spring is depressed when the item of merchandise is attached to the sensor.

12. A sensor according to claim 11, wherein the primary switch indicates an unsecured state when the item of merchandise is not attached to the sensor and wherein the electrical circuit is configured to activate an alarm in response to the unsecured state.

13. A sensor according to claim 1, further comprising an auxiliary switch configured for attachment to a removable component of the item of merchandise and for indicating that the removable component of the item of merchandise has been subsequently detached from the auxiliary switch.

14. A merchandise security device for displaying an item of merchandise, comprising:
a sensor comprising a housing defining an interior cavity and an electrical circuit disposed within the interior cavity;
a main power cable containing one or more conductors connected to the electrical circuit at one end and adapted to be connected to an external source of power at the other end; and
a power adapter cord having a length and containing one or more conductors connected to the electrical circuit at one end and adapted to be connected to the item of merchandise at the other end;
wherein at least a portion of the length of the power adapter cord is retractable into the interior cavity defined by the housing to provide an aesthetically pleasing display of the item of merchandise on the merchandise security device.

15. A method of displaying an item of merchandise in an aesthetically pleasing manner with at least a portion of a length of a power adapter cord concealed from view, the method comprising:
providing a sensor configured for attachment to the item of merchandise, the sensor comprising a housing defining an interior cavity and an electrical circuit disposed within the interior cavity that is connected to a source of electrical power, the sensor further comprising a power adapter cord having a length and containing one or more conductors connected to the electrical circuit at one end and adapted for connection to the item of merchandise at the other end to supply electrical power from the source of electrical power to the item of merchandise;
attaching the sensor to the item of merchandise;
connecting the other end of the power adapter cord to the item of merchandise; and
retracting at least a portion of the length of the power adapter cord into the interior cavity defined by the housing.
